(19) United States
(12) Patent Application Publication
(10) Pub. No.: US 2018/0145034 A1
(43) Pub. Date: May 24, 2018

(54) Methods To Selectively Deposit Corrosion-Free Metal Contacts

(71) Applicant: Applied Materials, Inc., Santa Clara, CA (US)

(72) Inventors: Yi Xu, San Jose, CA (US); Feiyue Ma, San Jose, CA (US); Yu Lei, Belmont, CA (US); Kazuya Daito, Milipitas, CA (US); Vikash Banthia, Los Altos, CA (US); Kai Wu, Palo Alto, CA (US); Jenn Yue Wang, Santa Clara, CA (US); Mei Chang, Saratoga, CA (US)

(21) Appl. No.: 15/817,985

(22) Filed: Nov. 20, 2017

Related U.S. Application Data
(60) Provisional application No. 62/424,536, filed on Nov. 20, 2016.

(51) Int. Cl. H01L 23/532; H01L 21/02; H01L 21/768; H01L 21/3205; H01L 23/528; H01L 21/285

(52) U.S. Cl. CPC H01L 23/53209; H01L 21/02068; H01L 21/76846; H01L 21/32053; H01L 21/76877; H01L 21/76882; H01L 23/528; H01L 21/76864; H01L 21/7685; H01L 21/28568; H01L 23/53266

(57) ABSTRACT

Methods of forming a contact line comprising cleaning the surface of a cobalt film in a trench and forming a protective layer on the surface of the cobalt, the protective layer comprising one or more of a silicide or germide. Semiconductor devices with the contact lines are also disclosed.

### CROSS-REFERENCE TO RELATED APPLICATIONS

This application claims priority to U.S. Provisional Application No. 62/424,536, filed Nov. 20, 2016, the entire disclosure of which is hereby incorporated by reference herein.

### TECHNICAL FIELD

The present disclosure relates generally to methods of depositing and metal contacts. In particular, the disclosure relates to processes of depositing cobalt contacts that are substantially corrosion-free.

### BACKGROUND

As FINFETs evolve towards smaller nodes (<10 nm), cobalt is replacing traditional tungsten as metal contact and local interconnects because of its low line resistance and void-free gap fill capability at narrow trenches of <20 nm.

However, severe Co corrosion inside the cobalt trench including significant undercut and recess are created after the wet clean following the dry etch of dielectric stack to open contact holes (via) and photo resist ashing. Both the undercut and recess are huge obstacles to achieve good gap for next metal contact formation, and cause very high contact resistance and device reliability issue.

A major reason of Co corrosion is that cobalt can react with wet chemical solutions and be dissolved in the form of ions because of its low electro potential than oxygen reduction in water:

Co²⁺(aq)→Co(−0.28V) (I)

O₂+2H₂O+4e⁻→4OH⁻(+0.4V) (II)

Additionally, if there is a different metal such as tungsten, which can work as cathode, then a galvanic corrosion happens. Galvanic corrosion can even happen without a second metal and cause missing cobalt in resultant structure.

Moreover, during the gap fill above Co trenches, there might be some void or seam or weak adhesion along the sidewall. During the following chemical-mechanical planarization (CMP) step, those are exposed to CMP corrosive chemicals (such as H₂O₂) and might let the chemicals penetrate down to erode Co and cause missing cobalt and therefore open circuits.

Therefore, a layer that is resistant to the attacks of moisture and wet chemical is needed. For tungsten contact, tungsten itself is resistant to moisture attack and some wet chemical attack (depending on specific chemical and pH value).

### SUMMARY

One or more embodiments of the disclosure are directed to methods of forming a contact line. A substrate surface having a trench with cobalt therein is provided. The surface of the cobalt is cleaned and a protective layer is formed thereon. The protective layer comprises one or more of a silicide or germanide.

Additional embodiments of the disclosure are directed to methods of forming a contact line. The methods comprise providing a substrate surface having a cobalt trench in a dielectric block. The surface of the cobalt is cleaned by one or more of baking the substrate in H₂, exposing the substrate to an H₂ plasma or sputtering the cobalt surface in an argon plasma with optional additional elements in an amount greater than about 0.5 atomic percent. A protective layer is formed on the surface of the cobalt. The protective layer comprises one or more of a silicide or germanide. Forming the protective layer comprises soaking the cobalt in one or more of silane, disilane, trisilane, tetrasilane, a higher order silane, a silyl halide without fluorine atoms, germane, digermane, trigermane, tetragermane, a higher order germane or a germanium halide without fluorine atoms, the soaking occurring at a temperature in the range of about 200 C to about 600 C, wherein a silicide is formed without plasma. The substrate with the protective layer is annealed by exposing the substrate to an anneal environment at a temperature in the range of about 300 C to about 600 C. The anneal environment comprises Ar, N₂, Ar/H₂, N₂/H₂, H₂, He or NH₃. A cobalt film is deposited on the substrate over the protective layer. The cobalt film is deposited by one or more of CVD or PVD, with an optional anneal to reflow the cobalt film.

Further embodiments of the disclosure are directed to semiconductor device contact lines comprising a substrate having a surface with a trench having a bottom and sidewalls. A dielectric layer is on the sidewalls of the trench. A cobalt gapfill material is within the trench between the sidewalls. The cobalt gapfill material is bounded by the dielectric layer. A protective layer is on the cobalt layer. The protective layer comprises one or more of a silicide or germanide. A tungsten liner is on top of the protective layer and tungsten metal is on top of the tungsten liner.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a cross-sectional schematic view of a semiconductor device in accordance with one or more embodiment of the disclosure;

FIG. 2 shows a cross-sectional schematic view of a semiconductor device in accordance with one or more embodiment of the disclosure; and

FIG. 3 shows a cross-sectional schematic view of a semiconductor device in accordance with one or more embodiment of the disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present invention, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

Embodiments of the disclosure advantageously provide methods to selectively form a conducting protective layer on top of cobalt. Some embodiments advantageously provide methods which can be performed either right after cobalt CMP or after the opening of a via or trench on top of the cobalt. Some embodiments advantageously provide methods using processing chambers integrated with gases including silanes (such as SiH₄, SiH₂Cl₂, Si₂H₆) and germanes (such as GeH₄, GeH₂Cl₂). This layer can be composed of either silicon or germanium or even any other film that can be selectively grown on cobalt and become a conducting layer with post treatments, such as plasma treatment, thermal anneal, UV bake and so on. Some embodiments advantageously form a conducting layer by a thermal process, i.e., without plasma exposure.

After formation, the protective layer can be, for example, a silicide or germanide of a metal, for example, cobalt. In some embodiments, formation of the protective layer is followed by deposition of a liner for the following via or trench gap fill, which can be in an integrated system. The selective deposition can be done in an integrated system without vacuum break.

In some embodiments, the methods comprise baking a substrate in an H₂ environment at 250-500 degree Celsius to reduce cobalt oxide or halides from previous processes. The substrate is soaked in a silane or germane for a certain amount of time at about 250-500 degree Celsius. The substrate can then be optionally annealed (based on, for example, the thermal budget, resistivity and/or reflow status).

In some embodiments, the methods comprise exposing the substrate to an H₂ (can be mixed other inertial gases) plasma at >200 degree Celsius to reduced oxide, halide and carbon contamination on the metal (e.g., cobalt) surface. The substrate is soaked in a silane or germane for a certain amount of time at about 250-500 degree Celsius. An optional anneal can follow (based on, for example, the thermal budget, resistivity and/or reflow status).

In some embodiments, the substrate is sputtered with an Ar plasma or H₂ plasma or Ar/H₂ mixture plasma to clean the metal (e.g., cobalt) top surface. The substrate can then be soaked in a silane or germane for a certain amount of time at about 250-500 degree Celsius. An optional anneal can follow (based on, for example, the thermal budget, resistivity and/or reflow status.)

To form a good ohmic contact between the underlying metal (e.g., cobalt) and top silicide or germide, some embodiments have an integrated preclean (such as H₂ bake, H₂ plasma, Ar plasma, Ar and H₂ plasma) before the following silicidation or germaniding.

In some embodiments, the methods advantageously provide corrosion-resistant cobalt silicide or germanide at the top so that the cobalt undercut and recess during top via or trench opening can be significantly reduced. This may lead to the significant improvement of a following via or trench gap fill, and lower contact resistance. In some embodiments, the methods advantageously provide corrosion-resistant cobalt silicide or germanide that can also block the path of CMP wet chemical to penetrate down and prevent cobalt corrosion. In one or more embodiments, the methods advantageously provide a silane or germane soak that may also modulate the via or trench sidewall condition, and improve the following gap fill and further minimize wet chemical corrosion.

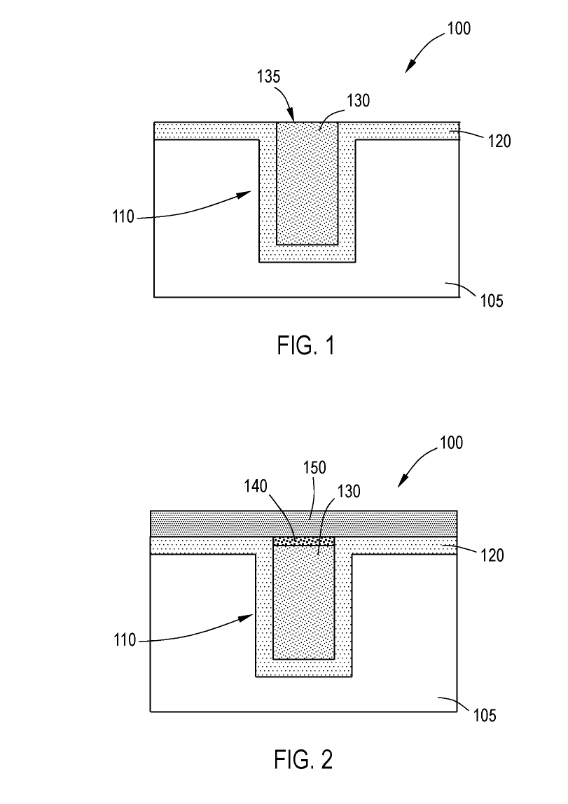

With reference to FIGS. 1 and 2, one or more embodiments are directed to methods of forming a semiconductor device 100. A substrate 105 is provided with a trench 110 filled with cobalt 130. The cobalt 130 has a surface 135 that is exposed for further processing.

An optional dielectric liner 120 can be formed on the substrate 105 or trench 110. The dielectric liner 120 can be any suitable dielectric material including, but not limited to, nitride, oxides or carbides of titanium or silicon. The dielectric liner 120 can be formed conformally on the substrate 105 and the trench 110 or non-conformally.

The cobalt 130 can be deposited by any suitable process including, but not limited to, chemical vapor deposition (CVD), atomic layer deposition (ALD) or physical vapor deposition (PVD). In some embodiments, the cobalt 130 film (also referred to as a layer or gapfill material) is deposited by CVD. In some embodiments, the cobalt 130 film is deposited by ALD.

The surface 135 of the cobalt 130 is cleaned to remove contaminants (e.g., oxides, halides or carbides) from the surface 135. In some embodiments, the surface 135 is cleaned by baking the substrate in a hydrogen environment.

In some embodiments, the hydrogen environment is a thermal environment without plasma exposure. In one or more embodiments, the hydrogen environment comprises a plasma for at least a portion of the total cleaning time.

In some embodiments, the surface 135 is cleaned by sputtering. The surface 135 is exposed to a plasma that sputters material from the surface 135 of the cobalt 130 layer. The sputtering plasma can include one or more of argon, helium, neon or krypton. In some embodiments, the sputtering plasma comprises substantially only argon. As used in this manner, “substantially only” means that the plasma gas is greater than 99.5 atomic percent of the stated species. In some embodiments, the plasma gas comprises argon in a concentration greater than or equal to about 90%, 95%, 98% or 99% argon on an atomic basis.

In some embodiments, the sputtering plasma includes additional elements to tune the amount of surface sputtering. The amount of the additional elements is greater than or equal to about 0.5 atomic percent. In some embodiments, the sputtering plasma includes additional elements in an amount greater than or equal to about 1%, 2%, 3%, 4%, 5%, 10%, 15% or 20% on an atomic basis. The additional elements can be any suitable elements including but not limited to, boron, arsenic, phosphorous, lithium, sodium or hydrogen.

After cleaning the surface 135, a protective layer 140 is formed on the surface 135 of the cobalt 130, as shown in FIG. 2. The protective layer 140 of some embodiments comprises one or more of a silicide or a germanide.

In some embodiments, forming the protective layer 140 comprises forming a cobalt silicide layer. The cobalt silicide can be formed by soaking the cobalt 130 in a silicon-containing compound. The silicon-containing compound of some embodiments comprises one or more of silane, disilane, trisilane, tetrasilane, a higher order silane or a silyl halide. In some embodiments, the silicon-containing compound is a silyl halide with substantially no fluorine atoms. As used in this regard, “substantially no fluorine atoms” means that there is less than 5, 4, 3, 2 or 1 atomic percent fluorine atoms based on all of the halogen atoms.

In some embodiments, forming the protective layer 140 comprises soaking the cobalt 130 in a germanium-containing compound. The germanium-containing compound of some embodiments comprises one or more of germane, digermane, trigermane, tetragermane, a higher order germane or a germanium halide. In some embodiments, the germanium-containing compound is a germanium halide with substantially no fluorine atoms.

Forming the protective layer 140 can occur at any suitable temperature. In some embodiments, the protective layer 140 is formed at a temperature in the range of about 200 C to about 600 C, or in the range of about 300 C to about 500 C, or about 400 C.

The protective layer 140 can be formed with or without plasma exposure during soaking. In some embodiments, forming the protective layer 140 without plasma forms a discrete silicide or germanide layer on the cobalt. In one or more embodiments, the protective layer is discrete and separate from the cobalt layer with a defined interface or very small interface region. The cobalt 130 and protective layer 140 of some embodiments are not a homogeneous or fixed gradient from the bottom of the cobalt to the top of the cobalt. The thickness of the protective layer 140 can be in the range of about 1 nm to about 50 nm, or in the range of about 2 nm to about 40 nm, or in the range of about 3 nm to about 30 nm.

The protective layer 140 of some embodiments is formed at a pressure in the range of about 0.5 Torr to about 100 Torr, or in the range of about 1 Torr to about 50 Torr, or in the range of about 5 Torr to about 25 Torr. In some embodiments, the protective layer 140 is formed by soaking the cobalt 130 for a time in the range of about 1 second to about 300 seconds.

In some embodiments, the protective layer 140 is annealed after formation. Annealing can be done by any suitable process at any suitable temperature. Suitable processes include, but are not limited to, plasma anneal, spike anneal, rapid thermal anneal, plasma anneal and thermal anneal. In some embodiments, annealing comprises exposing the substrate to an anneal environment at a temperature in the range of about 300 C to about 600 C. In some embodiments, the anneal environment comprising Ar, N₂, Ar/H₂, N₂/H₂, H₂, He or NH₃. The anneal pressure of some embodiments is in the range of about 100 mTorr to about 300 Torr, or in the range of about 1 Torr to about 200 Torr, or in the range of about 10 Torr to about 100 Torr.

After formation of the protective layer 140, a metal film 150, as shown in FIG. 2 is deposited on the substrate 105 over the protective layer 140. The metal film 150 of some embodiments comprises cobalt. The metal film 150 of some embodiments consists essentially of cobalt. As used in this regard, “consists essentially of cobalt” means that the metal film 150 is greater than or equal to about 99 atomic percent cobalt. The metal film 150 can be formed by any suitable process including, but not limited to, CVD, ALD or PVD. In some embodiments, the metal film 150 is annealed to reflow the film to form a more homogeneous film.

In some embodiments, cleaning the cobalt film 130, forming the protective layer 140 and annealing the protective layer 140 are performed without an air break in the process. This can be done by use of an integrated or cluster system in which the substrate is moved between chambers in a controlled vacuum environment.

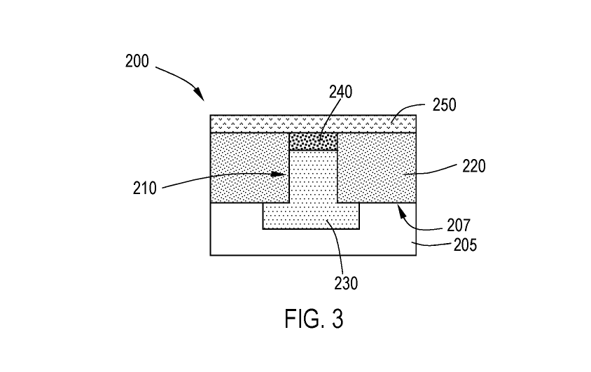

Referring to FIG. 3, some embodiments of the disclosure are directed to a semiconductor device 200. In some embodiments, the semiconductor device 200 comprises a contact line. A substrate 205 is provided that has a surface 205 with a trench 210 formed therein. The trench 210 can be a trench like that shown in FIG. 2, or can be a via or irregularly shaped trench, like that shown in FIG. 3.

A dielectric layer 220 is formed on the sidewalls of the trench 210. The dielectric layer 220 shown in FIG. 3 is also referred to as a dielectric block. A cobalt 230 gapfill material is within the trench 210 between the sidewalls. The cobalt 230 gapfill material can be bounded by an optional metal nitride layer between the cobalt 230 gapfill material and the dielectric layer 220.

A protective layer 240 is formed on the cobalt 230 gapfill material so that the top of the cobalt 230 gapfill material is covered by the protective layer 240. In some embodiments, the protective layer 240 comprises one or more of a silicide or germanide.

In some embodiments, a metal film 250 is formed on top of the dielectric layer 220 and the cobalt 230 gapfill material. The metal film 250 can be any suitable metal including, but not limited to, tungsten or cobalt. In some embodiments, a tungsten liner is on top of the protective layer as the metal film 250. In some embodiments a tungsten liner is a relatively thin layer formed on the dielectric and protective layer and has a thicker bulk deposited tungsten or cobalt metal formed thereon. In some embodiments, a cobalt liner is on top of the protective layer as the metal film. In some embodiments, a cobalt liner is a relatively thin layer formed on the dielectric and protective layer had has a thicker bulk deposited tungsten or cobalt metal layer thereon.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system,” and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A method of forming a contact line, the method comprising:
providing a substrate surface having a trench with cobalt therein;
cleaning a surface of the cobalt; and
forming a protective layer on the surface of the cobalt, the protective layer comprising one or more of a silicide or germanide.

2. The method of claim 1, wherein cleaning the surface of the cobalt comprises baking the substrate in H₂.

3. The method of claim 1, wherein cleaning the surface of the cobalt comprises exposing the substrate to an H₂ plasma.

4. The method of claim 1, wherein cleaning the surface of the cobalt comprises sputtering the surface of the cobalt with an argon plasma.

5. The method of claim 4, wherein the argon plasma further comprises additional elements in an amount greater than about 0.5 atomic percent.

6. The method of claim 1, wherein forming the protective layer comprises forming a cobalt silicide.

7. The method of claim 6, wherein forming the cobalt silicide comprises soaking the cobalt in a silicon-containing compound at a temperature in the range of about 200 C to about 600 C.

8. The method of claim 7, wherein the silicon-containing compound comprises one or more of silane, disilane, trisilane, tetrasilane, a higher order silane or a silyl halide.

9. The method of claim 8, wherein the silyl halide comprises substantially no fluorine atoms.

10. The method of claim 6, wherein silicide is formed without plasma exposure.

11. The method of claim 1, wherein forming the protective layer comprises soaking the cobalt in a germanium-containing compound at a temperature in the range of about 200 C to about 600 C

12. The method of claim 11, wherein the germanium-containing compound comprises one or more of germane, digermane, trigermane, tetragermane, a higher order germane or a germanium halide.

13. The method of claim 12, wherein the germanium halide comprises substantially no fluorine atoms.

14. The method of claim 1, wherein forming the protective layer occurs at a pressure in the range of about 0.5 to about 100 Torr.

15. The method of claim 14, wherein forming the protective layer occurs a time in the range of about 1 to about 300 seconds.

16. The method of claim 1, further comprising annealing the substrate with the protective layer.

17. The method of claim 16, wherein annealing comprises exposing the substrate to an anneal environment at a temperature in the range of about 300 to about 600, the anneal environment comprising Ar, N₂, Ar/H₂, N₂/H₂, H₂, He or NH₃.

18. The method of claim 1, further comprising depositing a cobalt film on the substrate over the protective layer, the cobalt film deposited by one or more of CVD or PVD with an optional anneal to reflow the cobalt film.

19. A method of forming a contact line, the method comprising:
providing a substrate surface having a cobalt trench in a dielectric block;
cleaning a surface of the cobalt by one or more of baking the substrate in H₂, exposing the substrate to an H₂ plasma or sputtering the cobalt surface in an argon plasma with optional additional elements in an amount greater than about 0.5 atomic percent;
forming a protective layer on the surface of the cobalt, the protective layer comprising one or more of a silicide or germanide, wherein forming the protective layer comprises soaking the cobalt in one or more of silane, disilane, trisilane, tetrasilane, a higher order silane, a silyl halide without fluorine atoms, germane, digermane, trigermane, tetragermane, a higher order germane or a germanium halide without fluorine atoms, the soaking occurring at a temperature in the range of about 200 C to about 600 C, wherein a silicide is formed without plasma;
annealing the substrate with the protective layer by exposing the substrate to an anneal environment at a temperature in the range of about 300 C to about 600 C, the anneal environment comprising Ar, N₂, Ar/H₂, N₂/H₂, H₂, He or NH₃; and
depositing a cobalt film on the substrate over the protective layer, the cobalt film deposited by one or more of CVD or PVD with an optional anneal to reflow the cobalt film.

20. A semiconductor device contact line comprising:
a substrate having a surface with a trench formed therein, the trench having a bottom and sidewalls;
a dielectric layer on the sidewalls of the trench;
a cobalt gapfill material within the trench between the sidewalls, the cobalt gapfill material bounded by the dielectric layer;
a protective layer on the cobalt layer, the protective layer comprising one or more of a silicide or germanide;
a tungsten liner on top of the protective layer; and
tungsten metal on top of the tungsten liner.
